(19) United States
(12) Patent Application Publication
(10) Pub. No.: US 2015/0179491 A1
(43) Pub. Date: Jun. 25, 2015

(54) ROBOTIC SYSTEM AND DETECTION METHOD

(71) Applicant: KABUSHIKI KAISHA YASKAWA DENKI, Kitakyushu-shi (JP)

(72) Inventors: Shinichi KATSUDA, Kitakyushu-shi (JP); Yoshiki KIMURA, Kitakyushu-shi (JP)

(73) Assignee: KABUSHIKI KAISHA YASKAWA DENKI, Kitakyushu-shi (JP)

(21) Appl. No.: 14/555,579

(22) Filed: Nov. 27, 2014

(30) Foreign Application Priority Data
Dec. 19, 2013 (JP) 2013-262217

(51) Int. Cl. H01L 21/68; B25J 9/16; B25J 11/00

(52) U.S. Cl. CPC H01L 21/681; B25J 11/0095; B25J 9/1679; Y10S 901/02

(57) ABSTRACT

A robotic system includes: an arm configured to carry a substrate to a mounting base; a hand disposed at a tip portion of the arm, the hand being configured to hold the substrate when the substrate is carried; a detector disposed on the hand, the detector being configured to detect the substrate; and an acquirer configured to recognize heights of the detector when the substrate is detected at a first position and a second position by the detector as heights of the substrate at respective positions and acquire a mounted-state of the substrate mounted on the mounting base based on the height of the substrate at the first position and the height of the substrate at the second position.

### CROSS-REFERENCE TO RELATED APPLICATION

This application claims priority from Japanese Patent Application No. 2013-262217 filed with the Japan Patent Office on Dec. 19, 2013, the entire content of which is hereby incorporated by reference.

### BACKGROUND

1. Technical Field

An embodiment of the disclosure relates to a robotic system and a detection method.

2. Description of the Related Art

A substrate such as a semiconductor wafer or a liquid crystal has become larger and thinner. The substrate deflects when it is mounted on an alignment device, and this deflection becomes larger as the diameter of the substrate becomes larger. The large diameter of the substrate may result in errors in edge detection of the substrate.

For this reason, there has been known a technique of detecting the deflection of a substrate (for example, see Japanese Patent No. 4853968). According to this technique, the Fresnel diffraction is analyzed using a received beam pattern obtained when parallel laser beams are emitted toward a line sensor. A distance between the optical axes of a line sensor and an edge position of the substrate is thereby obtained.

### SUMMARY

A robotic system includes: an arm configured to carry a substrate to a mounting base; a hand disposed at a tip portion of the arm, the hand being configured to hold the substrate when the substrate is carried; a detector disposed on the hand, the detector being configured to detect the substrate; and an acquirer configured to recognize heights of the detector when the substrate is detected at a first position and a second position by the detector as heights of the substrate at respective positions and acquire a mounted-state of the substrate mounted on the mounting base based on the height of the substrate at the first position and the height of the substrate at the second position.

### BRIEF DESCRIPTION OF THE DRAWINGS

FIG. 1 is a pattern diagram illustrating a robotic system according to an embodiment;

FIG. 2 is a perspective view illustrating a configuration of a robot;

FIG. 3 is a perspective view illustrating a configuration of a hand;

FIG. 4 is a block diagram illustrating a configuration of the robotic system;

FIG. 5A is a side view illustrating a wafer mounted on a mounting base and the hand;

FIG. 5B is a top view illustrating the wafer mounted on the mounting base and the hand;

FIG. 6A is a perspective view illustrating the wafer mounted in an inclined state on the mounting base;

FIG. 6B is a diagram illustrating a result of detecting the wafer in an inclined state;

FIG. 7A is a perspective view illustrating the wafer mounted in a deflected state on the mounting base;

FIG. 7B a diagram illustrating a result of detecting the wafer in a deflected state;

FIG. 8 is a diagram illustrating a configuration of an alignment device;

FIG. 9A is a top view illustrating the wafer mounted in a horizontal state on the mounting base;

FIG. 9B is a top view illustrating the wafer mounted in an inclined state on the mounting base;

FIG. 9C is a top view illustrating the wafer mounted in a deflected state on the mounting base;

FIG. 10 is a view illustrating a detector performing detection in another way;

and

FIG. 11 is a flowchart illustrating a procedure performed by the robotic system.

### DESCRIPTION OF THE EMBODIMENTS

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A robotic system according to one embodiment includes an arm, a hand, a detector, and an acquirer. The arm carries a substrate to a mounting base. The hand is disposed at the tip portion of the arm, and holds the substrate when the substrate is carried. The detector is disposed on the hand, and detects the substrate. The acquirer recognizes heights of the detector when the detector detects the substrate at a first position and a second position as heights of the substrate at the respective positions, then acquires mounted-states of the substrate on the mounting base based on the height of the substrate at the first position and the height of the substrate at the second position.

According to one embodiment, a mounted-state of the substrate can be detected with high accuracy.

The following describes in detail an embodiment of a robotic system and a detection method, which are disclosed in this application, with reference to the attached drawings. It is noted that the following embodiment does not limit the content of this disclosure.

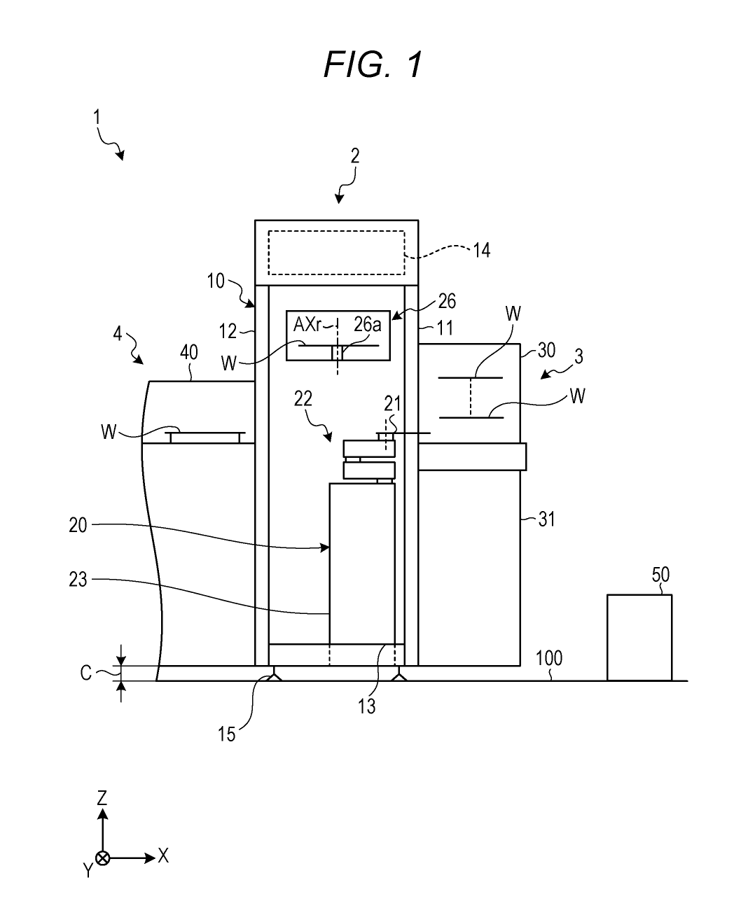

A robotic system 1 according to the embodiment will be described with reference to FIG. 1. FIG. 1 is a pattern diagram illustrating the robotic system 1 according to the embodiment. It is noted that, for clear explanation, FIG. 1 illustrates a three-dimensional orthogonal coordinate system including a Z-axis that places a vertically upward direction as to a positive direction and a vertically downward direction (that is, vertical direction) as a negative direction. Accordingly, a direction along the XY plane refers to a horizontal direction. Such an orthogonal coordinate system may be illustrated in other drawings used in the following descriptions.

The robotic system 1 of FIG. 1 includes a substrate conveyor 2, a substrate supplier 3, and a substrate processor 4, and a controller 50. The robotic system 1 is disposed on an installation surface 100. The substrate conveyor 2 includes a housing 10, a robot 20, and an alignment device 26.

The housing 10 includes a base installation frame 13, a filter unit 14, and leg tools 15. The housing 10 is, what is called, an Equipment Front End Module (EFEM), which generates a down flow of clean air through the filter unit 14. This down flow keeps the inside of the housing 10 in a high cleanliness state.

The base installation frame 13 is a bottom wall portion of the housing 10. The leg tools 15 are mounted to the inferior surface of the base installation frame 13. The leg tools 15 support the housing 10 with keeping a predetermined clearance C between the housing 10 and the installation surface 100.

The robot 20 includes a hand 21, an arm portion 22, and a base 23. The base 23 is disposed on the base installation frame 13. Also, the arm portion 22 is supported by the base 23, and can move in the vertical direction and swing in the horizontal direction with respect to the base 23.

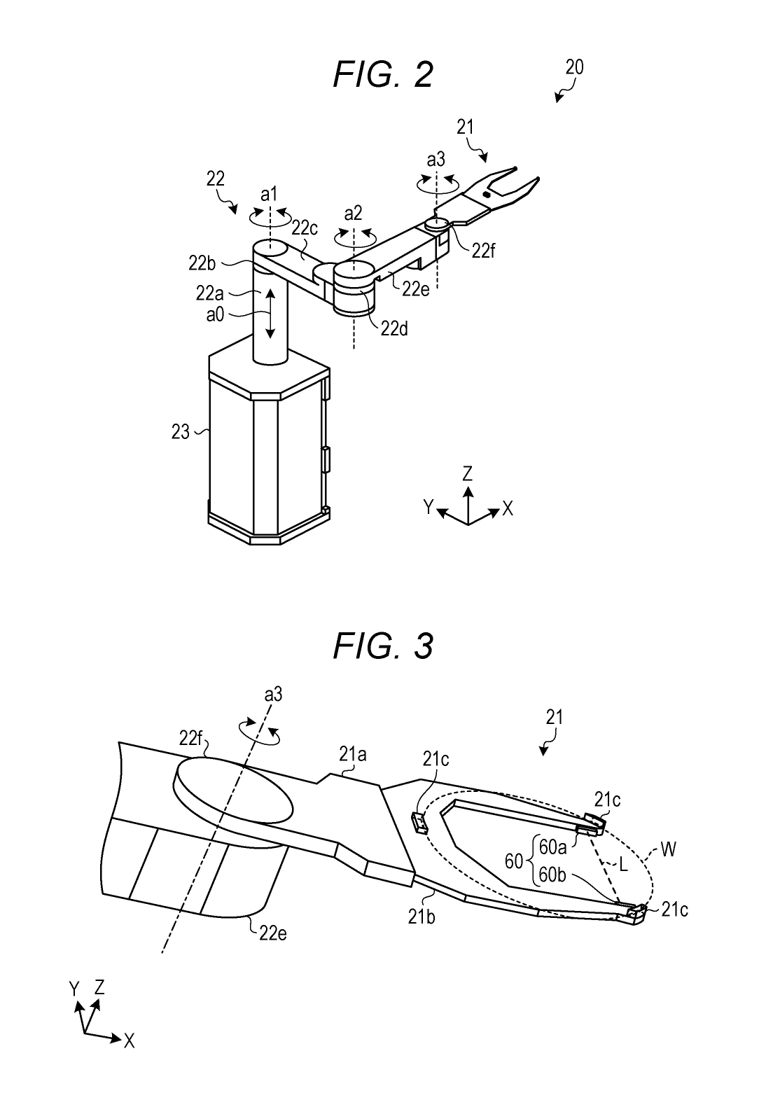

The hand 21 holds a substrate, which is an object to be carried. This embodiment describes a case where the robot 20 carries a wafer W (semiconductor wafer) as one example of a substrate. However, a substrate to be carried is not limited to the wafer W. For example, a substrate to be carried may be a liquid crystal substrate. The robot 20 is further described below in detail with reference to FIG. 2.

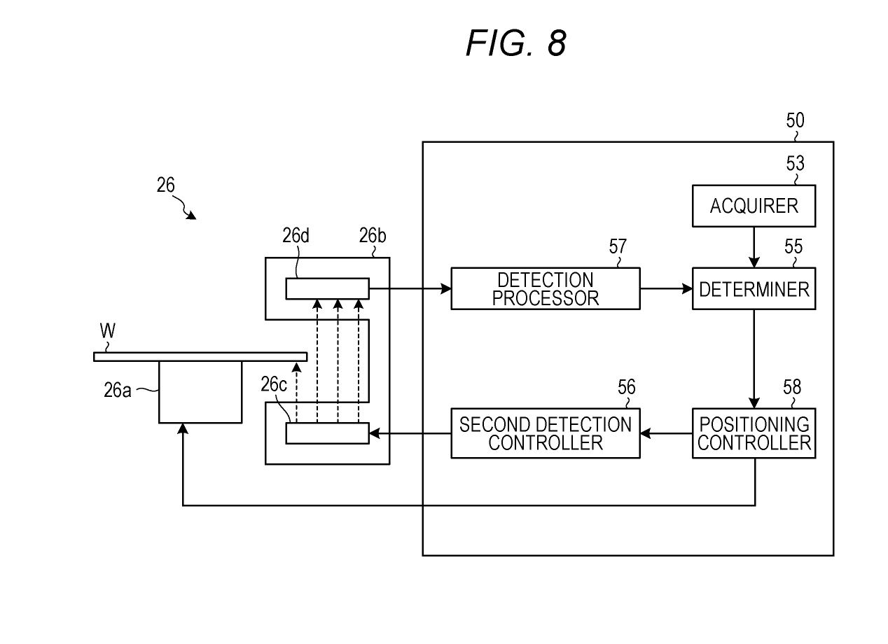

The alignment device 26 includes a mounting base 26a on which the wafer W is mounted. The mounting base 26a rotates around a rotation axis AXr that is parallel to the Z-axis. The alignment device 26 causes the mounting base 26a, on which the wafer W is mounted, to rotate, and positions the wafer W. The alignment device 26 is further described below in detail with reference to FIG. 8.

The substrate supplier 3 is disposed on a side surface 11 of the housing 10. The substrate supplier 3 includes a Front Opening Unified Pod (FOUP) 30, a FOUP opener (not illustrated), and a table 31 on which the FOUP 30 and the FOUP opener are placed.

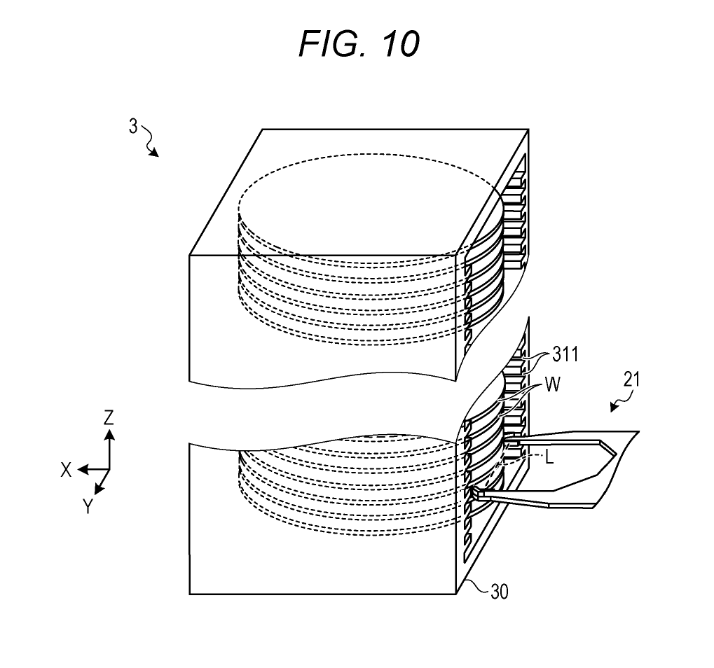

The FOUP 30 stores a plurality of wafers W in multiple stages in a height direction. The FOUP opener opens and closes a lid (not illustrated) of the FOUP 30 to allow the wafer W in the housing 10 to be taken out. Incidentally, more than one pair of the FOUP 30 and the FOUP opener may be disposed on the table 31 together with being spaced a predetermined distance from one another. The FOUP 30 is further described below in detail with reference to FIG. 10.

The substrate processor 4 performs, on the wafer W, the predetermined process steps in the semiconductor fabrication process such as a cleaning step, a film formation step, and a photolithography step.

The substrate processor 4 includes a process apparatus 40 which performs the predetermined process steps. The process apparatus 40 is disposed on the side surface 12 of the housing 10 such that the process apparatus 40 is faced to the substrate supplier 3, for example, with placing the robot 20 between them.

FIG. 1 illustrates a case where the substrate supplier 3 and the process apparatus 40 are disposed to be faced to each other. However, the positional relationship between the substrate supplier 3 and the process apparatus 40 is not limited to this. For example, the substrate supplier 3 and the process apparatus 40 may be disposed on the same side surface, or may be respectively disposed on two side surfaces that are adjacent to each other.

The controller 50 is disposed outside of the housing 10. In the example of FIG. 1, the controller 50 is disposed on the installation surface 100. The controller 50 is coupled to the robot 20 and the alignment device 26 via a cable (not illustrated).

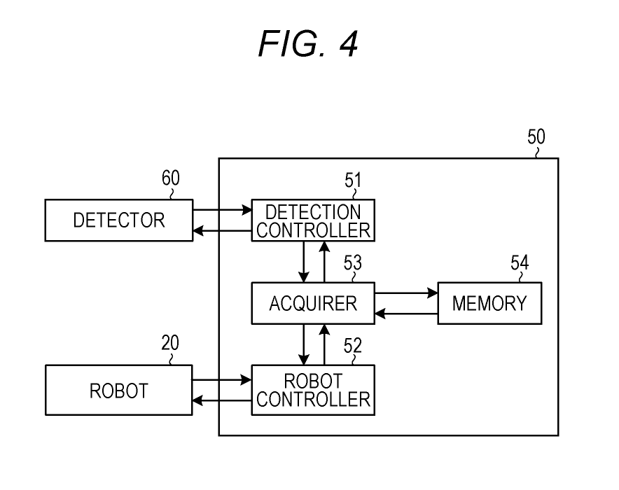

The controller 50 controls the operations of various devices that are coupled to the controller 50 via the cable. The controller 50 includes an arithmetic processor and a memory or a similar component. The controller 50 is further described below in detail with reference to FIG. 4.

FIG. 1 illustrates the controller 50 which is disposed outside of the housing 10. Instead, the controller 50 may be disposed inside of the housing 10. In addition, a plurality of controllers such as a controller to control the robot 20 and a controller to control the alignment device 26 may be respectively disposed.

In this case, the respective controllers may be disposed outside of the housing 10 or may be disposed inside of the housing 10. Alternatively, the respective controllers may be disposed inside of the robot 20 and inside of the alignment device 26 respectively.

The controller 50 controls, for example, the operation of the robot 20. In particular, the controller 50 controls the operation of the robot 20 based on the teaching data that is stored in advance. Alternatively, the controller 50 may obtain the teaching data from a host unit (not illustrated) every time the controller 50 controls the robot 20. In this case, the host unit may always monitor the state of the robot 20 (and each component of the robot 20).

The robot 20 takes out a wafer W stored in the FOUP 30 by performing vertically moving operation and swing operation in response to the instructions from the controller 50. Then the robot 20 mounts the wafer W, which is taken out from the FOUP 30, to the mounting base 26a of the alignment device 26.

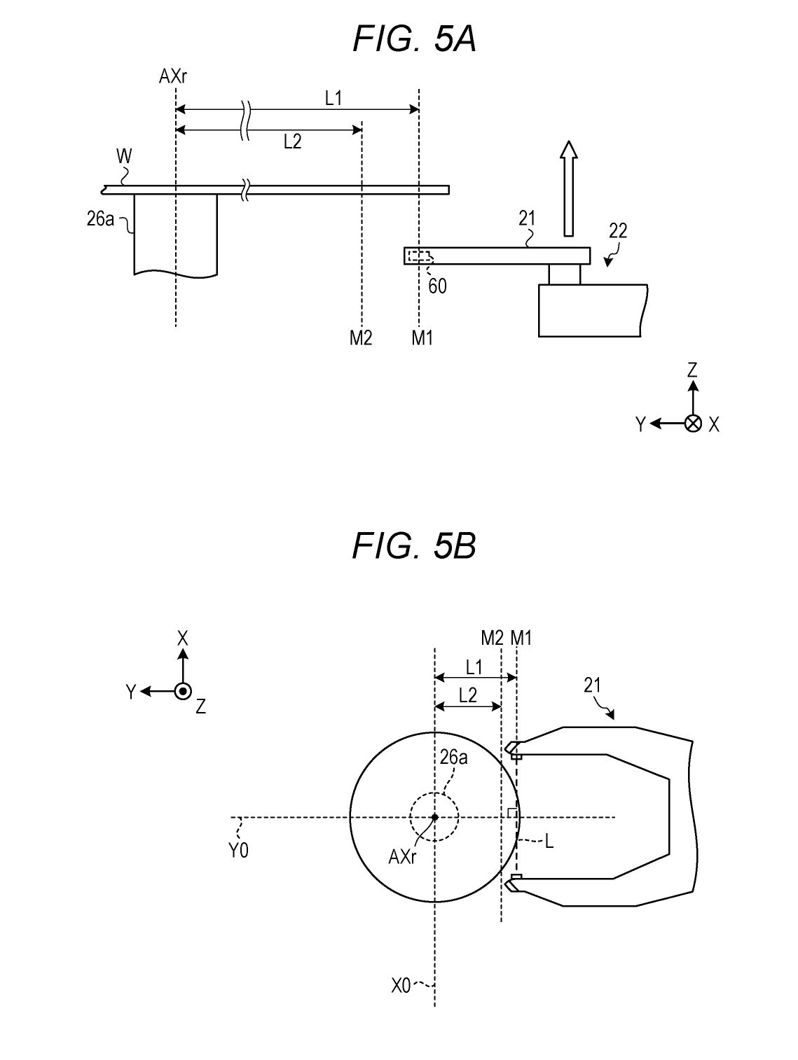

The controller 50 acquires a mounted-state of the wafer W. Note that a method for acquiring a mounted-state is described below with reference to FIGS. 5A and 5B.

The alignment device 26 positions the wafer W by rotating the mounting base 26a in response to the instructions from the controller 50. The robot 20 carries the positioned wafer W into the process apparatus 40. The process apparatus 40 performs the predetermined process steps on the carried wafer W.

Upon completing the above-described process steps, the robot 20 takes out the wafer W from the process apparatus 40, and stores the wafer W into the FOUP 30. Thus, the robotic system 1 performs the predetermined process steps on the wafer W that has been stored in the FOUP 30, and then stores the processed wafer W into the FOUP 30 again.

The following describes a configuration of the robot 20 according to the present embodiment. FIG. 2 is a perspective view illustrating the configuration of the robot 20. The robot 20 includes the hand 21, the arm portion 22, and the base 23.

The arm portion 22 includes an ascending/descending portion 22a, a first joint portion 22b, a first arm 22c, a second joint portion 22d, a second arm 22e, and a third joint portion 22f. The base 23 also works as a base portion of the robot 20.

The ascending/descending portion 22a is disposed on the base 23, and causes the arm portion 22 to move in the vertical direction (Z-axis direction) (see a double-headed arrow a0 in FIG. 2). The first joint portion 22b is coupled to the ascending/descending portion 22a. Also, the first joint portion 22b rotates around an axis a1 (see a double-headed arrow around the axis a1 in FIG. 2). The first arm 22c is coupled to the first joint portion 22b. Thus, the first arm 22c rotates around the axis a1.

The second joint portion 22d is coupled to the first arm 22c. Also, the second joint portion 22d rotates around an axis a2 (see a double-headed arrow around the axis a2 in FIG. 2). The second arm 22e is coupled to the second joint portion 22d. Thus, the second arm 22e rotates around the axis a2.

The third joint portion 22f is coupled to the second arm 22e. Also, the third joint portion 22f rotates around an axis a3 (see a double-headed arrow around the axis a3 in FIG. 2).

The hand 21 is an end effector that holds the wafer W (see FIG. 1). Also, the hand 21 is coupled to the third joint portion 22f. Thus, the hand 21 rotates around the axis a3.

The robot 20 includes a driving source such as a motor (not illustrated). The robot 20 drives such a driving source based on the instructions from the controller 50 to perform the vertically moving operation that causes the ascending/descending portion 22a to ascend and descend, and the swing operation that causes the respective joint portions 22b, 22d and 22f to rotate.

The following describes the detail of the hand 21 according to the present embodiment with reference to FIG. 3. FIG. 3 is a perspective view illustrating the configuration of the hand 21. The hand 21 includes a plate support portion 21a, a plate 21b, lock portions 21c, and a detector 60. Note that FIG. 3 illustrates, with a dotted line, a wafer W held by the hand 21.

The plate support portion 21a is coupled to the third joint portion 22f, and supports the plate 21b. The plate 21b has a two-split leading edge shape (forked shape) that has two tip portions. FIG. 3 illustrates the plate 21b, which has a forked shape, as an example. However, the shape of the plate 21b is not limited to this.

The lock portions 21c are members to lock the wafer W when the hand 21 holds the wafer W. In FIG. 3, three lock portions 21c are respectively disposed at the two tip portions of the plate 21b and a base end of the tip portions (a root portion of the tip portions of the plate 21b).

Thus, the hand 21 locks and holds the wafer W at three points (with three lock portions 21c). The number and locations of the lock portions 21c are not limited to the example of FIG. 3. For example, four or more lock portions 21c may be disposed.

The detector 60 is an optical sensor including a light projecting portion 60a and a light receiving portion 60b. FIG. 3 illustrates the light projecting portion 60a being disposed at one of the two tip portions of the plate 21b, and the light receiving portion 60b being disposed at the other one of the two tip portions of the plate 21b.

The light projecting portion 60a and the light receiving portion 60b are disposed to be faced to each other. The detector 60 detects the existence of the wafer W between the light projecting portion 60a and the light receiving portion 60b based on whether or not the light receiving portion 60b receives light projected from the light projecting portion 60a. FIG. 3 indicates a trajectory of the light projected from the light projecting portion 60a as a detection line L.

Note that the detector 60 may be any sensor which can detect the existences of the wafer W at a first position M1 to a third position M3, which is described below. The location and type of the detector 60 are not limited to the above-described example.

The following describes a configuration of the robotic system 1 according to the present embodiment with reference to FIG. 4. FIG. 4 is a block diagram illustrating the configuration of the robotic system 1 according to the present embodiment. Note that FIG. 4 illustrates components used for explanation of the robotic system 1, while omits to illustrate general components. In addition, a configuration of the controller 50 is mainly described with reference to FIG. 4, and the explanation of the components which has been already described with reference to FIG. 1 may be simplified.

The controller 50 includes a detection controller 51, a robot controller 52, an acquirer 53, and a memory 54.

The detection controller 51 controls the detector 60. In particular, the detection controller 51 controls the light projecting portion 60a (see FIG. 3) to project light based on an instruction from the acquirer 53. Also, the detection controller 51 receives a detection result from the light receiving portion 60b (see FIG. 3) while the light projecting portion 60a projects the light. The detection controller 51 sends the detection result, which is received from the light receiving portion 60b, to the acquirer 53.

The robot controller 52 controls the robot 20. In particular, the robot controller 52 drives the driving source disposed in the robot 20 based on the instruction from the acquirer 53 to cause the robot 20 to perform vertically moving operation and swing operation or similar operation.

Thus, the robot controller 52 controls the robot 20 to cause the detector 60 disposed on the hand 21 to move to the predetermined position. Also, the robot controller 52 informs the acquirer 53 of the position of the hand 21.

The acquirer 53 controls the detector 60 and the robot 20 via the detection controller 51 and the robot controller 52 to acquire heights of the wafer W (heights at respective parts of the wafer W) which are detected by the detector 60 at respective positions in the horizontal direction.

The acquirer 53 acquires a mounted-state of the wafer W on the mounting base 26a based on a set of the heights at the respective parts of the wafer W, which are detected by the detector 60. Here, the mounted-state means that how the wafer W is mounted on the mounting base 26a. The mounted-state includes, for example, cases where the wafer W is mounted in a horizontal state, a deflected state, and an inclined state on the mounting base 26a.

The heights at respective parts of the wafer W vary depending on the mounted-state. For example, if the wafer W is mounted in a horizontal state, the heights at respective parts of the wafer W are approximately equal. On the other hand, if the wafer W is mounted in a deflected state, the heights of the wafer W decrease as it moves toward the outer peripheral portion of the wafer W. In addition, in a case where the wafer W is mounted in a deflected state and a case where the wafer W is mounted in an inclined state, the rates with which the heights at respective parts of the wafer W vary are different from each other.

Accordingly, in the present embodiment, the acquirer 53 compares the heights at respective parts of the wafer W detected at respective positions in the horizontal direction. This allows the acquirer 53 to detect variation in the heights at respective parts of the wafer W, and acquire a mounted-state of the wafer W.

The following describes a method with which the robotic system 1 acquires a mounted-state of the wafer W with reference to FIGS. 5A and 5B. FIG. 5A is a side view illustrating the wafer W mounted on the mounting base 26a and the hand 21. FIG. 5B is a top view illustrating the wafer W mounted on the mounting base 26a and the hand 21.

The acquirer 53 of the robotic system 1 controls the detection controller 51 and the robot controller 52 to detect the existence of the wafer W at the first position M1 and the existence of the wafer W at a second position M2.

Here, a description is given of the first position M1 and the second position M2 with reference to FIGS. 5A and 5B. As illustrated in FIG. 5A, the first position M1 is a position at a distance L1 from the rotation axis AXr of the mounting base 26a. The second position M2 is a position at a distance L2(L1>L2) from the rotation axis AXr.

In particular, as illustrated in FIG. 5B, the first position M1 is a position where a distance from the rotation axis AXr to the detection line L of the detector 60 is the distance L1. The second position M2 is a position where a distance from the rotation axis AXr to the detection line L of the detector 60 is the distance L2. Note that FIG. 5B illustrates an axis which passes through the rotation axis AXr and is parallel to the X-axis as an axis X0, and an axis which passes through the rotation axis AXr and is parallel to the Y-axis as an axis Y0.

A description is given of the operation of the acquirer 53 detecting the existence of the wafer W at the first position M1. Note that the operation for detecting the wafer W at the second position M2 is the same as the operation for detecting the wafer W at the first position M1, and therefore, the explanation thereof will be omitted.

First, the robot controller 52 controls the robot 20 such that the detector 60 is positioned at the first position M1. At this time, the robot controller 52 controls the robot 20 such that the height of the detector 60 is the predetermined height from the base installation frame 13.

Next, the robot controller 52 controls the robot 20 to move up the detector 60 (see an arrow in FIG. 5A). Instead of this, the detection controller 51 may move down the detector 60 from the predetermined height instead.

While the robot controller 52 moves up the detector 60, the detection controller 51 controls the detector 60 to detect the existence of the wafer W.

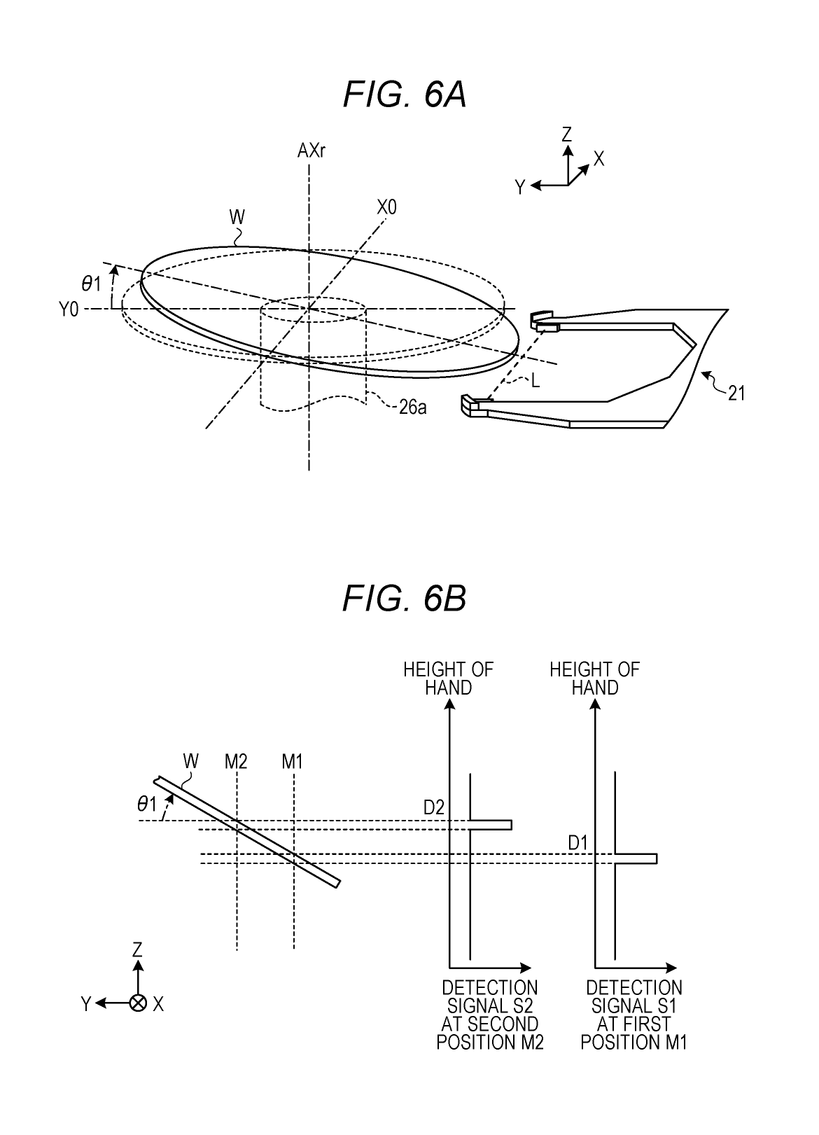

The following describes the detection results of the wafer W at the first position M1 and the second position M2 with reference to FIGS. 6A and 6B. FIG. 6A is a perspective view illustrating the wafer W mounted on the mounting base 26a. FIG. 6B is a diagram indicating the detection result of the wafer W.

Initially, the operation of the detector 60 will be described in detail. When the light receiving portion 60b receives light projected from the light projecting portion 60a, the detector 60 determines the wafer W does not exist on the detection line L to output a low signal. On the other hand, when the light receiving portion 60b receives no light, the detector 60 determines the wafer W exists on the detection line L to output a high signal.

Thus, a detection signal which indicates a detection result of the wafer W is a digital signal having two values, which are the high signal and the low signal. Hereinafter, a detection signal which indicates the detection result at the first position M1 is referred to as a first detection signal S1, and a detection signal which indicates the detection result at the second position M2 is referred to as a second detection signal S2.

The existence of the wafer W is detected with moving up the detector 60 mounted to the hand 21. In this view, a height of the detector 60, i.e., a height of the hand 21, when each detection signal becomes high signal is a height of the wafer W at each of the positions M1 and M2. In other words, the acquirer 53 recognizes a height of the detector 60 when the wafer W is detected at each of the positions M1 and M2 as a height of the wafer W at each position.

In the present embodiment, a height of the hand 21 at a fall time of the detection signal, at which each detection signal switches from high signal to low signal, represents a height of the wafer W at each of the positions M1 and M2. In FIG. 6B, the reference sign D1 indicates a height of the wafer W at the first position M1, while the reference sign D2 indicates a height of the wafer W at the second position M2.

As indicated in FIGS. 6A and 6B, when the wafer W is mounted on the mounting base 26a with a state of being inclined at an angle θ1 around the axis X0, a height D1 of the wafer W at the first position M1 is lower than a height D2 of the wafer W at the second position M2 (D1<D2).

The acquirer 53 compares the height D1 of the wafer W at the first position M1 with the height D2 of the wafer W at the second position M2. The acquirer 53 determines that the wafer W is mounted in an inclined state if the height D1 and the height D2 are different from each other. Otherwise, the acquirer 53 determines that the wafer W is mounted in a horizontal state.

Alternatively, the acquirer 53 may calculate an inclination amount a of the wafer W=(D1−D2)/(L−1L2)=tanθ1, and define the calculated inclination amount α as a mounted-state.

As described above, the acquirer 53 can determine that a mounted-state of the wafer W is a horizontal state or an inclined state by comparing the heights D1 and D2 of the wafer W at the two positions.

Note that, in FIGS. 6A and 6B, the height of the wafer W is defined as the height of the hand 21 at the fall time of each detection signal Instead of this, the height of the wafer W may be defined as, for example, the height of the hand 21 at the rise time of each detection signal (a time at which each detection signal switches from low signal to high signal). Alternatively, the height of the wafer W may be defined as a middle point between the height of the hand 21 at the fall time of each detection signal and the height of the hand 21 at the rise time of each detection signal.

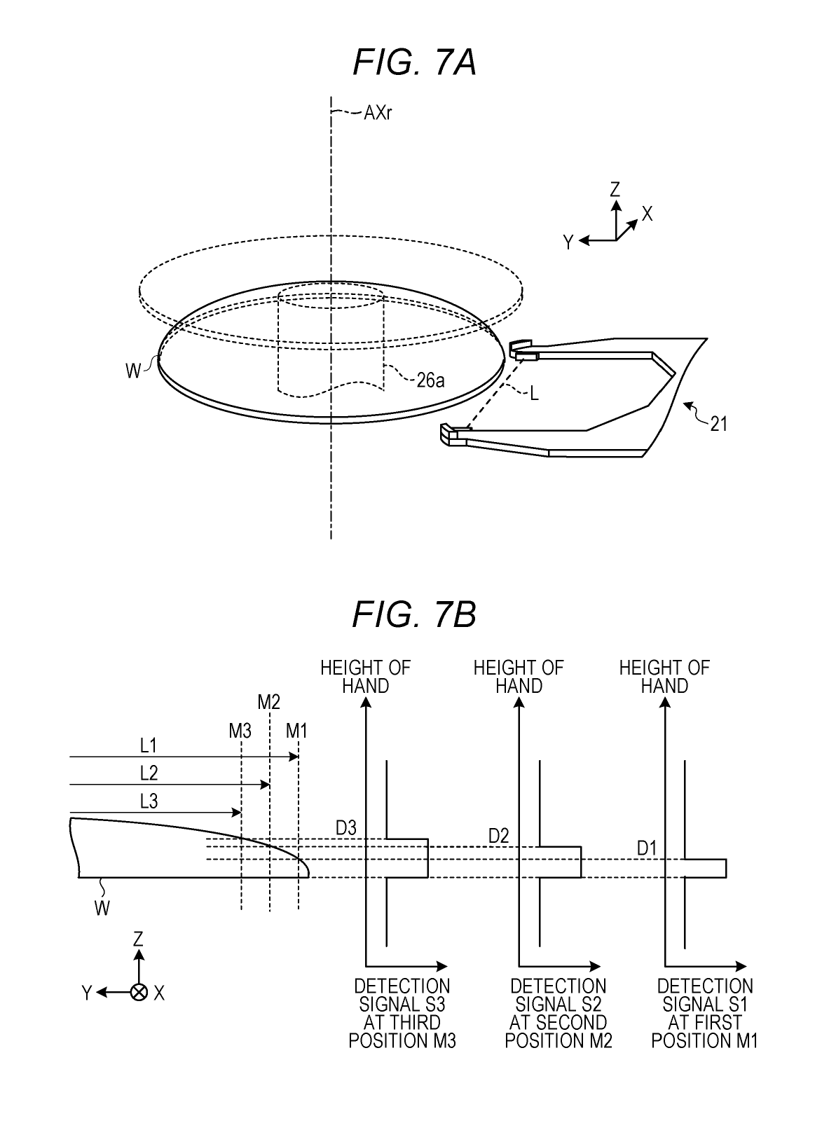

The following describes another method with which the robotic system 1 determines a mounted-state of the wafer W with reference to FIGS. 7A and 7B. FIG. 7A is a perspective view illustrating the wafer W mounted on the mounting base 26a. FIG. 7B is a diagram illustrating a result of detecting the wafer W.

In the method described with reference to FIGS. 5A and 5B, and FIGS. 6A and 6B, the mounted-state of the wafer W is determined based on the heights of the wafer W at two positions. In contrast to this, the following describes a method for determining a mounted-state of the wafer W based on the heights of the wafer W at three positions.

As illustrated in FIG. 7B, the acquirer 53 detects the existence of the wafer W at the first position M1, the second position M2, and the third position M3. Note that a method for detecting the wafer W at each of the positions M1 to M3 is the same as the method described with reference to FIGS. 5A and 5B, and FIGS. 6A and 6B, and therefore the explanation will be omitted. Namely, the acquirer 53 recognizes a height of the detector 60 when the wafer W is detected at the third position M3 as a height of the wafer W at the third position. The acquirer 53 may determine a mounted-state of the wafer W on the mounting base 26a based on the height of the wafer W at the first to third positions M1 to M3.

The detection result of the wafer W at the third position M3 is referred to as a third detection signal S3. In addition, the third position M3 is a position at a distance L3 (L3<L2<L1) from the rotation axis AXr of the mounting base 26a.

The acquirer 53 acquires the heights of the wafer W from respective detection signals S1 to S3. In FIG. 7B, the reference signs D1 to D3 respectively indicate the heights of the wafer W at the respective positions M1 to M3. In addition, a reference sign α12 indicates an inclination amount of the wafer W between the first position M1 and the second position M2; a reference sign α23 indicates an inclination amount of the wafer W between the second position M2 and the third position M3; and a reference sign α13 indicates an inclination amount of the wafer W between the first position M1 and the third position M3.

As illustrated in FIGS. 7A and 7B, when the wafer W is mounted in a deflected state, the height D3 is the highest and the height D1 is the lowest among the heights D1 to D3 (D3>D2>D1) of the wafer W.

The inclination amount (first inclination amount) α12 of the wafer W between the first position M1 and the second position M2 is represented as α12=(D1−D2)/(L1−L2). Similarly, the inclination amount (second inclination amount) α23 of the wafer W between the second position M2 and the third position M3 is represented as α23=(D2−D3)/(L2−L3). Furthermore, the inclination amount (third inclination amount) α13 of the wafer W between the first position M1 and the third position M3 is represented as α13=(D1−D3)/(L1−L3).

When the wafer W is mounted in a deflected state, the inclination amounts α12, α23, and α13 of the wafer W between respective positions M1 to M3 are different from one another (α12≠α23≠α13).

Accordingly, the acquirer 53 selects at least two inclination amounts from the inclination amounts α12, α23, and α13 of the wafer W between respective positions M1 to M3, and compares the selected inclination amounts. In this example, the acquirer 53 compares the inclination amounts α12 and α23, then determines that the mounted-state of the wafer W is a deflected state when the compared inclination amounts α12 and α23 are different from each other. [0079]

In addition, when the acquirer 53 determines that the mounted-state of the wafer W is not a deflected state, the acquirer 53 compares the height D1 of the wafer W at the first position M1 with the height D2 of the wafer W at the second position M2. The acquirer 53 determines that the mounted-state of the wafer W is an inclined state if the compared result indicates that the heights D1 and D2 are different from each other. When the acquirer 53 determines that the wafer W is not in a deflected state or in an inclined state, the acquirer 53 determines that the mounted-state of the wafer W is a horizontal state.

Note that, in this example, the acquirer 53 compares the inclination amount α12 of the wafer W between the first position M1 and the second position M2 with the inclination amount α23 of the wafer W between the second position M2 and the third position M3. Instead of this, the acquirer 53 may compare the inclination amount α12 with the inclination amount α13 of the wafer W between the first position M1 and the third position M3. Also, the acquirer 53 may compare all inclination amounts α12, α23, and α13.

The same applies to the height of the wafer W. The acquirer 53 may compare the height D1 with the height D3, or may compare all heights D1, D2, and D3.

In addition, if a distance (L1−L2) between the first position M1 and the second position M2 is equal to a distance (L2−L3) between the second position M2 and the third position M3, the inclination amounts α12 and α23 are respectively proportionate to differences between the heights (D1−D2, D2−D3). Accordingly, in this case, the acquirer 53 may compare the differences (D1−D2, D2−D3) between the heights instead of comparing the inclination amount α12 with the inclination amount α23.

Alternatively, the acquirer 53 may acquire a curved line which passes through the heights D1 to D3 of the wafer W, and may determine whether or not the mounted-state of the wafer W is a deflected state based on a curvature of the curved line. Also, the acquirer 53 may acquire a straight line which passes through the heights D1 to D3 of the wafer W, and may determine whether or not the mounted-state of the wafer W is an inclined state based on a slope of the straight line.

Alternatively, the acquirer 53 may acquire the slope (inclination amount a) of the straight line which passes through the heights D1 to D3 of the wafer W and the curvature (deflection amount 13) of the curved line which passes through the heights D1 to D3 of the wafer W, and may obtain the mounted-state of the wafer W based on the inclination amount a and the deflection amount β. Alternatively, the acquirer 53 may recognize the inclination amount α as an inclination angle of the wafer W, and the deflection amount β as a deflection angle.

Alternatively, the acquirer 53 may store in advance, in the memory 54, data obtained by associating the heights of the wafer W at respective positions M1 to M3 with the mounted-states of the wafer W. In this case, the acquirer 53 may refer to the above-described data, which is stored in the memory 54, based on the heights D1 to D3 of the wafer W to determine a mounted-state of the wafer W.

In this case, information, which is associated with the mounted-state of the wafer W, is not limited to the height of the wafer W. For example, the length of the high signal of each of the detection signals S1 to S3 may be associated with the mounted-state of the wafer W, and may be stored in the memory 54.

As described above, the acquirer 53 can determine that the mounted-state of the wafer W is any one of a horizontal state, an inclined state, or a deflected state by comparing the heights D1 to D3 of the wafer W at the three positions.

Note that, when the wafer W is deflected, the heights at rise times of respective detection signals S1 to S3 are approximately constant while the heights at fall times vary as illustrated in FIG. 7B. Accordingly, in FIG. 7B, the heights of the wafer W are defined as the heights of the hand 21 at the fall times of respective detection signals S1 to S3. Instead of this, the heights of the wafer W may be defined as, for example, the middle points between the heights of the hand 21 at the fall times and the heights the hand 21 at the rise times.

The following describes a method with which the alignment device 26 positions the wafer W based on the mounted-state of the wafer W with reference to FIG. 8. FIG. 8 is a diagram illustrating a configuration of the alignment device 26. FIG. 8 illustrates only components used for explanation of the alignment device 26, and omits to illustrate components, which have been already described, and general components.

The alignment device 26 includes the mounting base 26a and an edge detector 26b. The edge detector 26b includes a light source 26c and a line sensor 26d. The edge detector 26b corresponds to one example of a second detector.

The light source 26c and the line sensor 26d are disposed with being spaced from each other by a predetermined distance in a vertical direction such that the light source 26c and the line sensor 26d are faced to each other with sandwiching the wafer W mounted on the mounting base 26a.

As illustrated in FIG. 8, the light source 26c emits light based on a control signal input from a second detection controller 56. The light source 26c emits collimated light toward the line sensor 26d from below the wafer W.

The line sensor 26d is, for example, a charge-coupled device (CCD) line sensor which has one pixel row including a plurality of pixels (not illustrated) arranged in line. The line sensor 26d accumulates electric charges corresponding to a received light amount for each pixel.

The second detection controller 56 outputs a control signal based on an instruction from a positioning controller 58 to control the light source 26c. Also, a detection processor 57 reads out, as a detection signal, the electric charges accumulated in each pixel from the line sensor 26d. Further, the detection processor 57 detects an edge position of the wafer W and a chip in the wafer W based on the detection signal.

A determiner 55 determines whether or not the chip is a notch, which is preliminarily formed in the wafer W, based on the mounted-state of the wafer W input from the acquirer 53 and the information of the chip in the wafer W input from the detection processor 57.

Also, the determiner 55 outputs location information of the notch to the positioning controller 58 based on the above-described determination result and the edge position of the wafer W input from the detection processor 57.

The positioning controller 58 rotates the mounting base 26a based on the location information of the notch to position the wafer W.

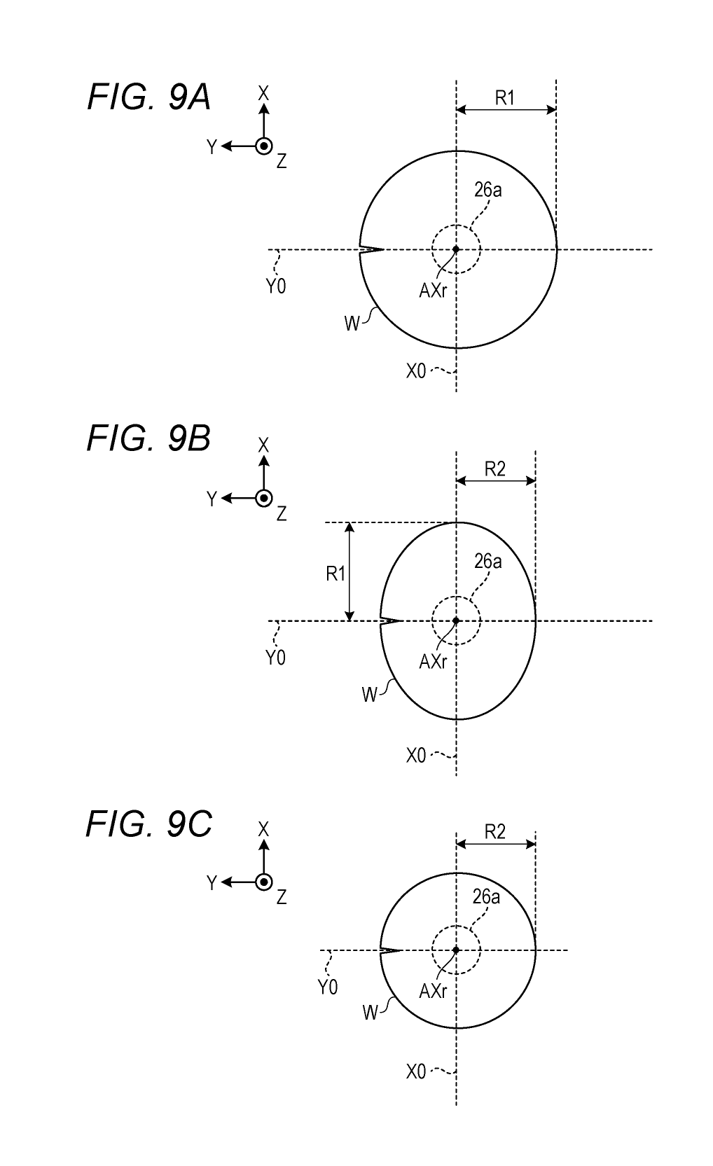

The following describes a method with which the alignment device 26 determines whether or not a chip formed in the wafer W is a notch based on a mounted-state of the wafer W with reference to FIGS. 9A to 9C. FIG. 9A is a top view illustrating the wafer W mounted in a horizontal state. FIG. 9B is a top view illustrating the wafer W mounted in an inclined state. FIG. 9C is a top view illustrating the wafer W mounted in a deflected state.

As illustrated in FIG. 9A, the wafer W has a circular shape having a radius R1 which is equal to a radius of the wafer when the wafer W is mounted in the horizontal state on the mounting base 26a. The detection processor 57 detects, as a chip formed in the wafer W, a portion where the edge position significantly varies.

The determiner 55 compares a shape of the chip of the wafer W with a shape of the notch, and determines whether or not the detected chip is the notch based on the comparison result. The determiner 55 outputs the location information of the chip which is determined to be the notch to the positioning controller 58.

Here, as illustrated in FIG. 9B, the wafer W can be seen as an elliptical shape having a long diameter R1 and a short diameter R2 (R1>R2) from the vertical direction when the wafer W is mounted in the inclined state on the mounting base 26a.

Also, as illustrated in FIG. 9C, the wafer W can be seen as a circular shape having a radius R2 (R1>R2), which is smaller than a radius of the wafer W, from the vertical direction if the wafer W is mounted in the deflected state on the mounting base 26a.

Thus, the edge position detected by detection processor 57 varies depending on the mounted-state of the wafer W. Therefore, if the detected chip is simply compared with the shape of the notch, the chip which is actually not the notch may erroneously be determined as the notch depending on the mounted-state of the wafer W.

Accordingly, the determiner 55 compares the shape of the chip with the shape of the notch based on the mounted-state of the wafer W input from the acquirer 53 to minimize the erroneous determination of the notch. In particular, the determiner 55 corrects the shape of the chip based on the mounted-state of the wafer W.

The determiner 55 compares the corrected shape of the chip with the shape of the notch to determine whether or not the chip is the notch.

Also, the determiner 55 may correct the edge position of the wafer W depending on the mounted-state of the wafer W, and may output the corrected edge position of the wafer W to the positioning controller 58.

In this example, the determiner 55 corrects the shape of the chip based on a mounted-state of the wafer W. Instead of this, the determiner 55 may correct the shape of the notch based on the mounted-state of the wafer W. Alternatively, the detection processor 57 may receive the mounted-state of the wafer W from the acquirer 53, and may correct the edge position of the wafer W, and may detect the chip based on the corrected edge position of the wafer W.

As described above, the determiner 55 determines whether or not the detected chip is the notch based on a mounted-state of the wafer W. This allows the determiner 55 to accurately detect the notch. Also, the determiner 55 positions the wafer W based on the mounted-state of the wafer W. This can enhance the positioning accuracy of the wafer W.

Incidentally, in the above-described embodiment, the description has been given to a case in which the detector 60 detects the height of the wafer W. Instead of this, the detector 60 may detect another detection object. The following describes a case in which the detector 60 detects a housed-state of the wafer W housed in the FOUP 30 with reference to FIG. 10. FIG. 10 is a view illustrating the detector 60 performing detection in another way.

As illustrated in FIG. 10, the substrate supplier 3 includes the FOUP 30. The FOUP 30 has grooves 311 to hold the wafer W, for example, in a horizontal state. In addition, the FOUP 30 can store a plurality of wafers W in multiple stages in the Z-axis direction.

The robot 20 (see FIG. 2) causes the tip of the hand 21 to run in the Z-axis direction from a predetermined position. Then, the detector 60 detects the existence of the wafer W based on whether or not the detection line L is blocked by the peripheral edge portion of the wafer W. Namely, the detector 60 also works as a mapping sensor which performs, what is called, mapping operation for detecting the number and locations of the wafers W housed in the FOUP 30.

Thus, the detector 60 may not only detect the heights of the wafers W, but also perform the mapping operation. Use of the detector 60, which detects the heights of the wafers W, as a mapping sensor eliminates a need for the robotic system 1 to include a mapping sensor other than the detector 60. This can reduce the equipment cost of the robotic system 1.

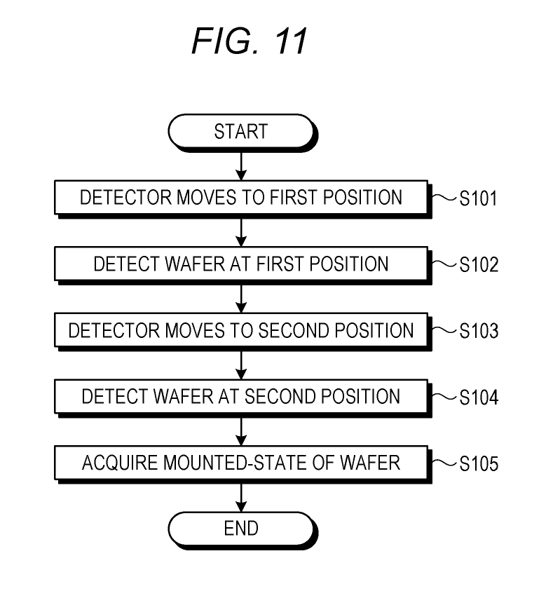

The following describes a procedure performed by the robotic system 1 according to the embodiment with reference to FIG. 11. FIG. 11 is a flowchart illustrating the procedure performed by the robotic system 1. Note that FIG. 11 illustrates, as one example, the procedure which determines a mounted-state of the wafer W based on the heights of the wafer W at two positions.

As illustrated in FIG. 11, the detector 60 moves to the first position M1 (step S101). Next, the detector 60 detects the wafer W at the first position M1 (step S102). In particular, while the robot 20 moves up the hand 21, the detector 60 detects the existence of the wafer W.

Subsequently, the detector 60 moves to second position M2 (step S103). The detector 60 detects the wafer W at the second position M2 (step S104).

Next, the acquirer 53 acquires a mounted-state of the wafer W based on the detection result of steps S102 and S104 (step S105). In particular, the acquirer 53 acquires the height D1 of the wafer W at the first position M1 and the height D2 of the wafer W at the second position M2 from the detection result of steps S102 and S104, and compares the heights D1 and D2 with each other. This allows the acquirer 53 to determine that the mounted-state of the wafer W is an inclined state or a horizontal state.

Note that FIG. 11 describes the procedure which determines the mounted-state of the wafer W based on the heights of the wafer W at two positions. A procedure which determines the mounted-state of the wafer W based on the heights of the wafer W at three positions may be possible by adding a step for detecting the wafer W at a third position to the process of FIG. 11.

As described above, the robotic system according to the embodiment includes the arm, the hand, the detector, and the acquirer. The detector detects a mounted-state of the substrate based on the heights of the substrate at a plurality of positions, and the acquirer acquires the detected mounted-state.

Accordingly, the robotic system according to the embodiment can detect the mounted-state of the substrate with high accuracy.

In addition, in the present embodiment, the mounted-state of the wafer W mounted on the mounting base 26a of the alignment device 26 is acquired. Instead of this, the mounted-state of the wafer W may be acquired by detection of the height of the wafer W housed in the FOUP 30. Alternatively, another mounting base other than that of the alignment device 26 may be provided, and the height of the wafer W mounted on the provided mounting base may be detected.

Further effects and modifications can be easily made by those skilled in the art. In view of this, the wider aspect of the present disclosure is not limited to the certain details and the typical embodiments represented and described above. Accordingly, various modifications can be made without departing from the spirit or scope of overall concept defined by accompanying claims and equivalents thereof.

Note that the acquirer 53 corresponds to one example of recognition means and acquisition means.

In addition, the embodiment of the disclosure may be the following first to sixth robotic system and the following first detection method. The first robotic system includes: an arm that carries a substrate to a mounting base; a hand disposed at a tip portion of the arm to hold the substrate when the substrate is carried; a detector disposed on the hand to detect the substrate; and an acquirer acquiring a mounted-state of the substrate mounted on the mounting base based on a height of the substrate detected by the detector at a first position and a height of the substrate detected by the detector at a second position.

In the second robotic system according to the first robotic system, the detector detects a housed-state of the substrate housed in a housing container.

The third robotic system according to the first or second robotic system detects a mounted-state of the substrate based on the heights of the substrate respectively detected at the first position and the second position by moving the hand in a height direction, the hand being positioned to be at the first position or the second position with touching a horizontal surface.

The fourth robotic system according to any one of the first to the third robotic systems further includes an alignment device rotating the mounting base to position the substrate.

In the fifth robotic system according to the fourth the robotic system, the alignment device corrects an edge position of the substrate based on the mounted-states of the substrate detected by the detector, and positions the substrate.

In the sixth the robotic system according to the fourth or the fifth robotic system, the alignment device includes a second detector detecting a chip formed in the substrate, and a determiner determining whether or not the chip detected by the second detector is a notch preliminarily formed in the substrate based on the mounted-state of the substrate detected by the detector.

The first detection method includes carrying a substrate to a mounting base, detecting the substrate, and acquiring a mounted-state of the substrate mounted on the mounting base based on a height of the substrate detected at the first position and a height of the substrate detected at the second position.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A robotic system comprising:
an arm configured to carry a substrate to a mounting base;
a hand disposed at a tip portion of the aim, the hand being configured to hold the substrate when the substrate is carried;
a detector disposed on the hand, the detector being configured to detect the substrate; and
an acquirer configured to recognize heights of the detector when the substrate is detected at a first position and a second position by the detector as heights of the substrate at respective positions, and acquire a mounted-state of the substrate mounted on the mounting base based on the height of the substrate at the first position and the height of the substrate at the second position.

2. The robotic system according to claim 1, wherein
the detector is configured to detect a housed-state of the substrate in a housing container.

3. The robotic system according to claim 1, wherein
the first position and the second position are positions on a horizontal surface, and
the robotic system further includes a robot controller configured to place the hand including the detector at the first position or the second position, and move the hand in a height direction.

4. The robotic system according to claim 1, wherein
the acquirer is configured to compare the height of the substrate at the first position with the height of the substrate at the second position, and determine that the substrate is mounted in an inclined state when the heights are different from each other.

5. The robotic system according to claim 1, wherein
the acquirer is configured to acquire an inclination amount of the substrate based on the height of the substrate at the first position, the height of the substrate at the second position, a distance from a rotation axis of the mounting base to the first position, and a distance from the rotation axis of the mounting base to the second position, and acquire the mounted-state of the substrate based on the inclination amount.

6. The robotic system according to claim 1, wherein
the acquirer is configured to
recognize a height of the detector when the substrate is detected at a third position by the detector as a height of the substrate at the third position, and
acquire a mounted-state of the substrate mounted on the mounting base based on the heights of the substrate at the first position to the third position.

7. The robotic system according to claim 6, wherein
the acquirer is configured to
acquire a first inclination amount of the substrate based on the height of the substrate at the first position, the height of the substrate at the second position, a distance from a rotation axis of the mounting base to the first position, and a distance from the rotation axis of the mounting base to the second position,
acquire a second inclination amount of the substrate based on the height of the substrate at the second position, the height of the substrate at the third position, the distance from the rotation axis of the mounting base to the second position, and a distance from the rotation axis of the mounting base to the third position, and
determine that the substrate is mounted in a deflected state when the first inclination amount and the second inclination amount are different from each other.

8. The robotic system according to claim 7, wherein
the acquirer is configured to
acquire a third inclination amount of the substrate based on the height of the substrate at the first position, the height of the substrate at the third position, the distance from the rotation axis of the mounting base to the first position, and the distance from the rotation axis of the mounting base to the third position, and
select two inclination amounts from the first to third inclination amounts to determine that the substrate is mounted in a deflected state when the selected two inclination amounts are different from each other.

9. The robotic system according to claim 6, wherein
the acquirer is configured to obtain a curved line passing through heights of the substrate at the first to third positions, and determine whether or not the substrate is mounted in a deflected state based on a curvature of the obtained curved line.

10. The robotic system according to claim 6, wherein
the acquirer is configured to obtain a straight line passing through heights of the substrate at the first to third positions, and determine whether or not the substrate is mounted in an inclined state based on a slope of the obtained straight line.

11. The robotic system according to claim 6 further comprising
a memory storing data obtained by associating the mounted-states of the substrate with the heights of the substrate at the first position, the second position, and the third position, wherein
the acquirer is configured to acquire the mounted-states of the substrate based on the data and the heights of the substrate at the first to third positions.

12. The robotic system according to claim 1 further comprising
an alignment device configured to rotate the mounting base to position the substrate.

13. The robotic system according to claim 12, wherein
the alignment device is configured to correct an edge position of the substrate based on the mounted-state of the substrate acquired by the acquirer, and position the substrate.

14. The robotic system according to claim 12, wherein
the alignment device includes a second detector configured to detect a chip formed in the substrate, and a determiner configured to determine whether or not the chip detected by the second detector is a notch that is formed in advance based on the mounted-state of the substrate acquired by the acquirer.

15. A method comprising:
carrying a substrate to a mounting base;
detecting the substrate at a first position and a second position; and
acquiring a mounted-state of the substrate on the mounting base based on the height of the substrate when the substrate is detected at the first position and the height of the substrate when the substrate is detected at the second position.

16. A robotic system comprising:
recognition means for recognizing heights of a detector when a substrate mounted on a mounting base is detected by the detector at a first position and a second position as heights of the substrate at the respective positions; and
acquiring means for acquiring a mounted-state of the substrate mounted on the mounting base based on the height of the substrate at the first position and the height of the substrate at the second position.
